(19) United States
(12) Patent Application Publication
(10) Pub. No.: US 2009/0268771 A1
(43) Pub. Date: Oct. 29, 2009

(54) Multi-Stripe Laser Diode Desings Which Exhibit a High Degree of Manufacturability

(76) Inventors: John A. Patchell, Dublin (IE); James C. O'Gorman, Dublin (IE)

Correspondence Address: BROOKS, CAMERON & HUEBSCH , PLLC, 1221 NICOLLET AVENUE , SUITE 500, MINNEAPOLIS, MN, 55403, US

(21) Appl. No.: 11/991,687

(22) PCT Filed: Sep. 6, 2006
(86) PCT No.: PCT/EP2006/066061

§ 371 Date: Aug. 5, 2008

(30) Foreign Application Priority Data
Sep. 8, 2005 (IE) S2005/0587

(51) Int. Cl. H01S 5/00; H01L 21/00

(52) U.S. Cl. 372/50.12; 438/34; 438/23; 257/E21.002

(57) ABSTRACT

The present application is directed at providing a new lasing device having increased production yields over other single mode laser devices. In particular, a semiconductor lasing device is provided having at least two lasing devices formed on a common substrate. The lasing device is arranged so that in use a preferred lasing device is operational and remaining lasing devices are redundant. This redundancy improves the production yield since only one of the lasing devices needs to function correctly as the others are unused.

### FIELD OF THE APPLICATION

The present Application relates to semiconductor laser devices and methods of manufacturing laser devices.

### BACKGROUND TO THE APPLICATION

The production yields of single mode, single section, edge emitting laser diodes are much lower than those of ridge waveguide Fabry Perot lasers. There are two principal reasons for this, the general reliability of such devices and the fabrication tolerances required to make them.

A reason for the poor reliability of these single mode devices is the fact that the fabrication of these devices usually requires several epitaxial growth steps. After the first epitaxial growth a grating is formed on the surface of the wafer using well photolithographic techniques. This means that the second wafer growth step is initiated upon a damaged uneven crystal surface. As a result lasers fabricated in this way have relatively high defect densities and are thus intrinsically less reliable than devices fabricated in a single epitaxial growth step.

A second reason for the reduced production yields of these devices compared with Fabry Perot lasers is due to the inability to cleave the wafer into laser bars with sufficient accuracy. This means that in a significant proportion of the devices the cleaved facets are incorrectly positioned with respect to the wavelength selective filters (gratings in the case of DFB's) within these devices. This incorrect positioning in turn results in large numbers of devices which have unsatisfactory side mode suppression ratios, or do not operate in a single longitudinal mode over a useful temperature range.

It would be advantageous to alleviate the effects in the fabrication process of laser devices.

### DESCRIPTION

The present application uses the fact that in single stripe laser diodes only a very small percentage of the device's active region is used for the purpose of generating light and that accordingly there is space for including more than one laser device, with a subsequent step selecting the best laser device. It should be noted that some single mode, single section devices do not require two re-growth steps, the application as discussed below is also applicable to such devices.

Accordingly, the present application provides a laser device fabricated on a piece of semiconductor material, the laser device comprising at least a first lasing device and a second lasing device, whereby at least one of the lasing devices is intended to be redundant. This will be explained further with reference to and as shown in the accompanying drawings in which:

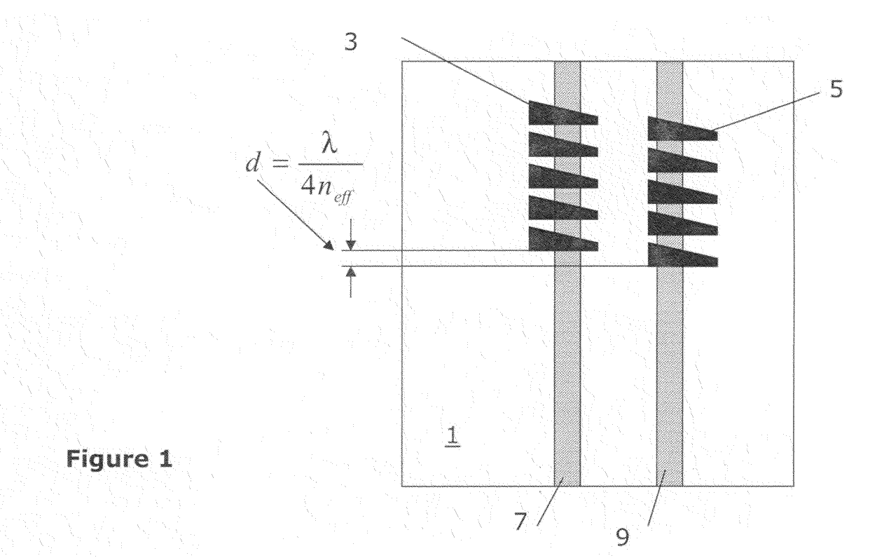

FIG. 1 illustrates a structure comprising two adjacent ridge waveguides staggered by a quarter wavelength with respect to each other,

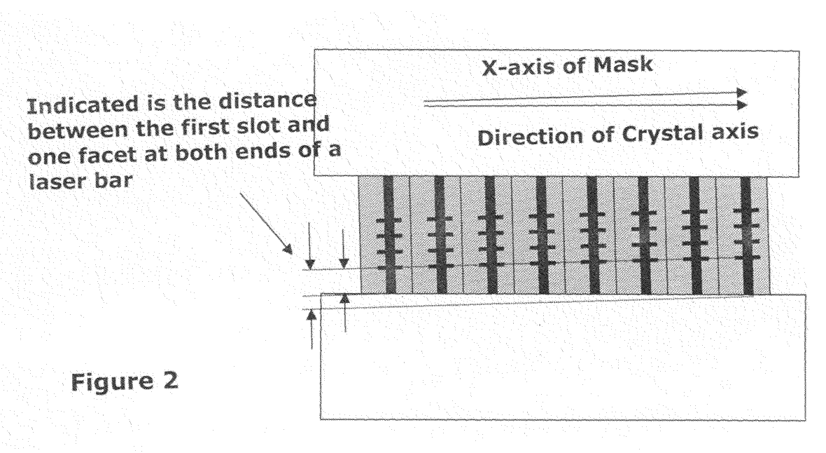

FIG. 2 illustrates how the perpendicular distances of corresponding features on different devices from either facet, varies between adjacent devices,

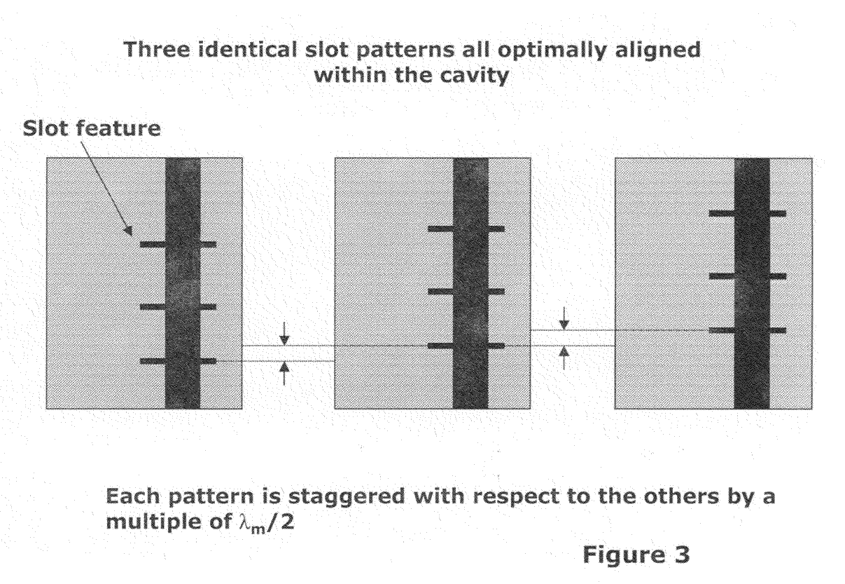

FIG. 3 shows three laser diodes with identical slot patterns,

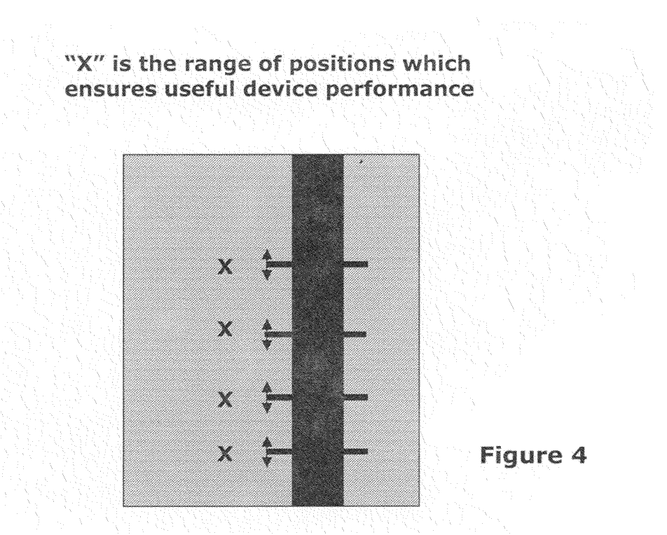

FIG. 4 illustrates that there is a range of positions around each optimum positions where the spectral properties of the device may be suitable for the application of interest,

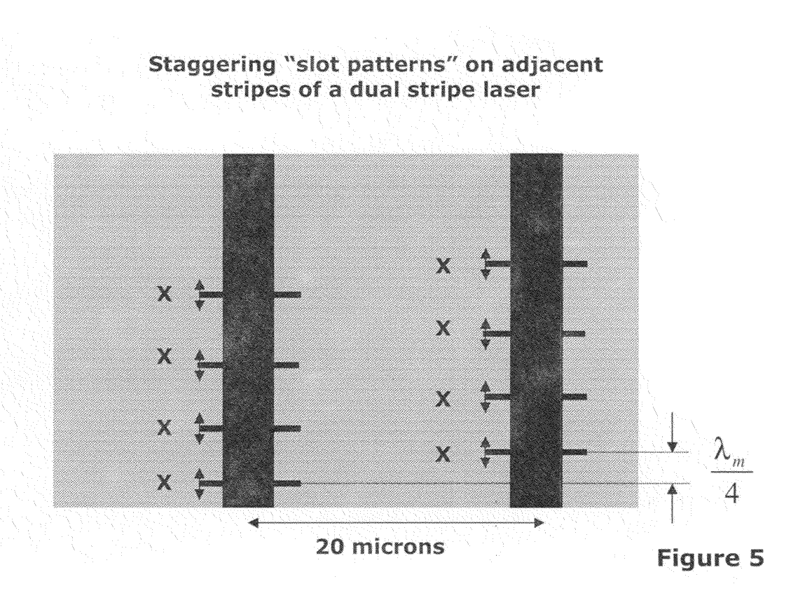

FIG. 5 illustrates a dual stripe laser,

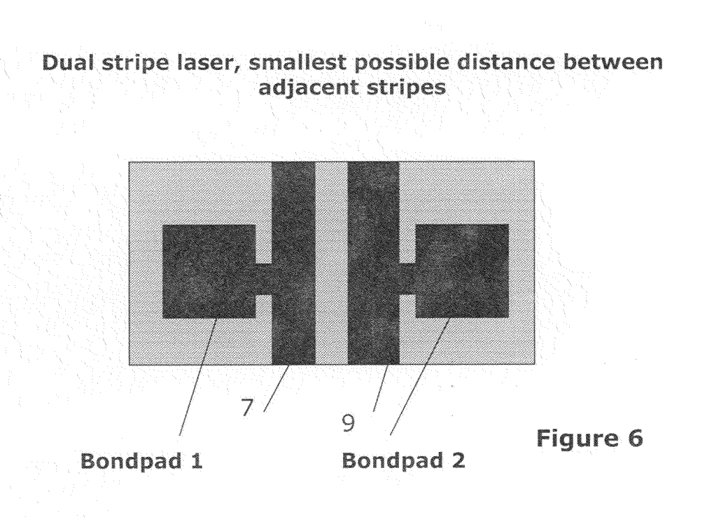

FIG. 6 shows an exemplary chip layout,

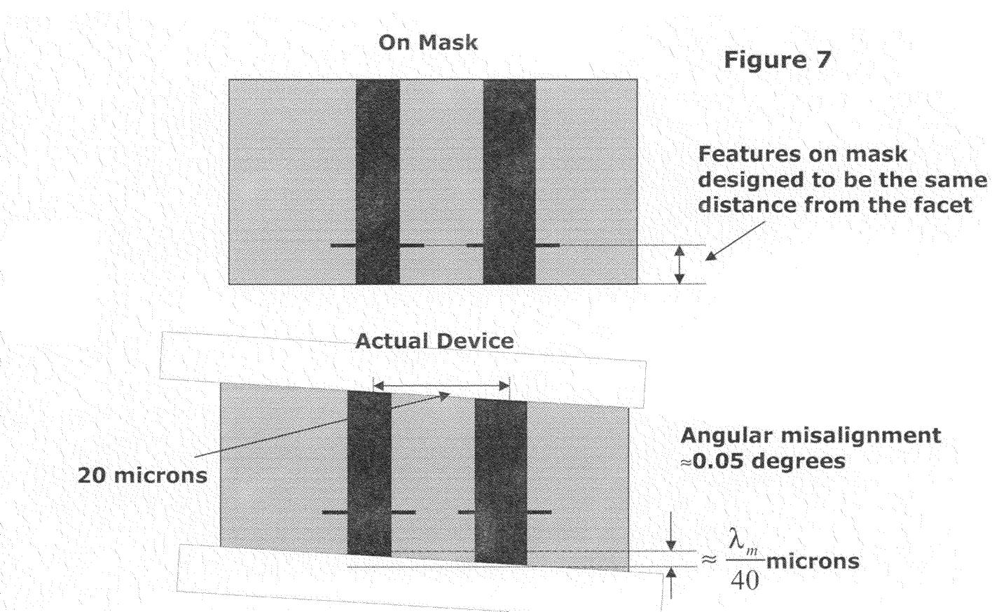

FIG. 7 illustrates a misalignment situation which may be used to advantage,

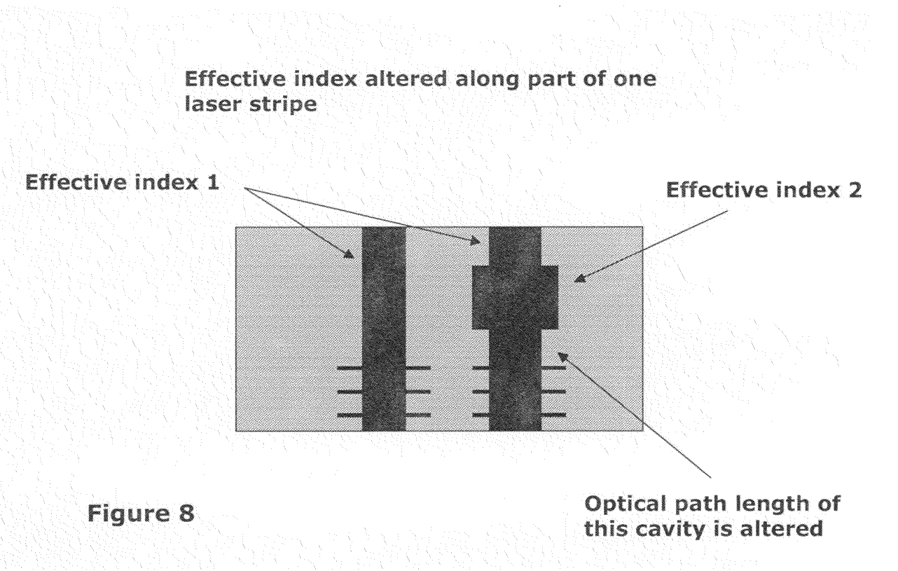

FIG. 8 shows an exemplary dual stripe laser,

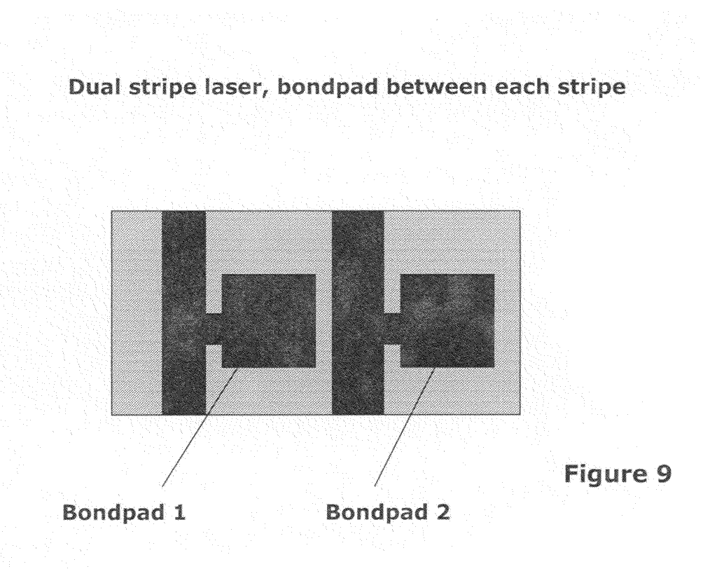

FIG. 9 illustrates an exemplary bond pad arrangement,

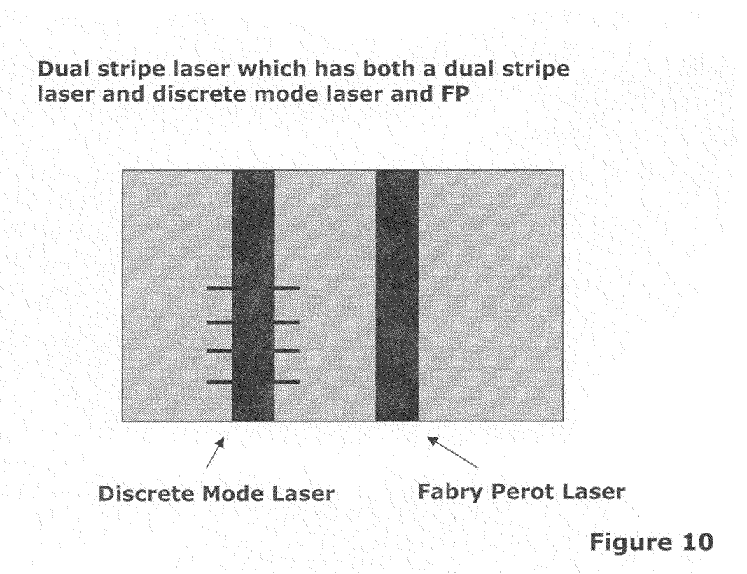

FIG. 10 illustrates an exemplary configuration employing two different types of lasing device, and

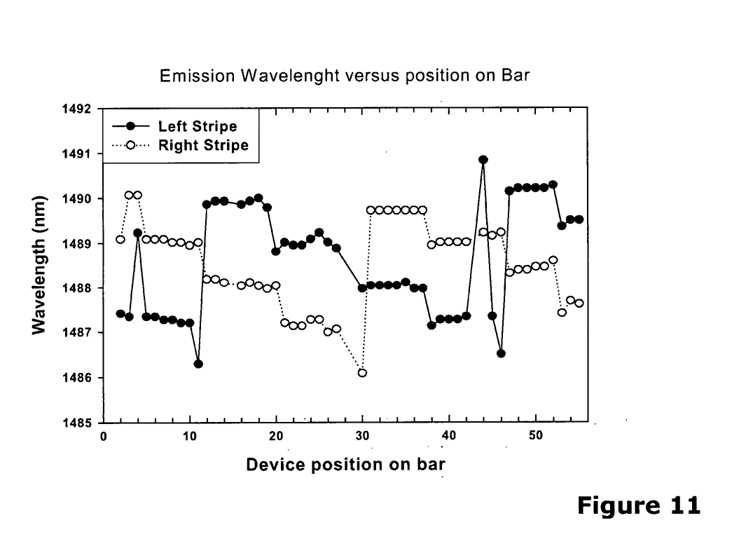

FIG. 11 shows the experimental results from a sample of over fifty adjacent dual type lasing devices.

As described above and as illustrated in FIG. 1, the present application provides a laser device 1 fabricated on a piece of semiconductor material, the laser device comprising at least a first lasing device and a second lasing device, whereby at least one of the lasing devices is intended to be redundant. During the manufacture process or a subsequent measurement or calibration process, a preferred lasing device is selected and the redundant lasing device disabled or deactivated. Bragg gratings or any other type of wavelength selective filter 3,5 defined on adjacent ridge waveguides 7,9 using photolithography or e-beam lithography may be staggered by a quarter wavelength with respect to each other. Given the above it is possible to construct laser diode chips containing two or more lasing stripes, each one optically isolated from each other. By defining wavelength selective filters 7,9 that are staggered with respect to each other on each of these stripes, it is significantly more likely that at least one these filters would be positioned correctly with respect to the facets. It will be appreciated that generally only the better of these two devices will be used and that the remaining device will be redundant. For example, both devices may be tested and the best device may be connected by means of a bond wire externally and the remaining inferior device left unconnected, i.e. effectively disabled. As the inferior device is not connected, it is not subsequently used after testing and from then on is redundant. In what follows we describe some of the factors that affect the alignment of wavelength selective filters with respect to the laser facets, and discuss methods of optimising the yield to multi-stripe devices. Throughout this document the term wavelength selective filters may refer to either patterns of etched slot features of the type discussed, for example, in Irish patent No. S83622, the entire contents of which are incorporated by reference, or other wavelength selective structures and that generally any slot type is compatible with this invention. It is further noted that the conclusions of the following discussion apply equally well to any wavelength selective filter that may be formed in the semiconductor by photolithography or e-beam lithography.

Before attempting to quantify improvements in production yields which this technique brings, a number of factors which affect how accurately the cleaved facets may be positioned with respect to the wavelength selective filters will be discussed. The two main factors which affect this are, the accuracy of the cleaver itself (typically ±2 microns), and the rotational accuracy with which lithographic patterns may be aligned to the wafer (this is typically better than ±0.005 degrees for contact lithography and better than ±0.04 degrees for optical steppers). Consider an exemplary bar of single stripe laser diode devices 15 mm in length, the bar consisting of 50 devices, 300 microns wide, each of which is supposedly identical. If the mask patterns and the crystal axis were perfectly aligned, then corresponding features on different devices would be equidistance from either facet. However because this is not the case, the perpendicular distances of corresponding features on different devices from either facet, varies linearly (or nonlinearly if the cleave jumps to a different crystal plane) from one device to the next (FIG. 2). Given a misalignment of up to ±0.04 degrees across a 15 mm bar could result in a change of up to 10.5 microns in the distance between a given lithographic feature and either facet. The sum of the errors discussed above is far greater than the wavelength of the light in the cavity, therefore the chances of correctly aligning the wavelength selective filter seem small. However things are not as bad as they seem. Consider a laser diode with a number of etched slot features that are optimally aligned with respect to the facets of the device. If the pattern is moved in either direction by a distance corresponding to half the material wavelength of light being selected, it will still be positioned optimally with respect to the facets. FIG. 3 shows three laser diodes with identical slot patterns, all of which are aligned optimally within the cavity. Also there will be a range of positions around each of these optimum positions where the spectral properties of the device will be suitable for the application of interest. We label this range “X” (see FIG. 4).

If for example in a single stripe device the probability that a randomly positioned wavelength selective filter is aligned correctly with respect to the facets is P_{f}. Then the probability that the filter will not be aligned correctly with the facets is 1−P_{f}. Then on an a device with N stripes, the probability that at least one of the wavelength filters will be correctly aligned to the cleaved facets is

1−(1−P_{f})^{N}.

However we may do better than this, consider FIG. 5. This illustration shows a dual stripe laser. The distance between adjacent slots on the same ridge is

$$d = \frac{{λ}_{m}}{2} ,$$

(typically the slot separations are a large multiples of this length) additionally the slot patterns are staggered with respect to each other by

$$d ≅ \frac{{λ}_{m}}{4} .$$

It is noted here that the material wavelength λₘ is equal to

$$\frac{λ}{{n}_{eff}}$$

(where n_{eff} is the effective index of the mode). We can see that this situation provides a high chance of at least one lasing stripe meeting the criteria for a given application. In the case where

$$X \geq \frac{{λ}_{m}}{4}$$

this approach should provide a yield of 100%. This is also the case if the distance between the slots on each ridge is a large multiple of,

$$\frac{{λ}_{m}}{2} ,$$

as is typically the case. However for this method to work well the two ridge waveguides guides should be positioned close enough to each other, so that the error in positioning lithographic features relative to the facet, on one ridge with respect to the other should be approximately

$$\frac{{λ}_{m}}{40} .$$

FIG. 6 shows one chip layout which allows this condition to be achieved. Larger errors will result in lower yields. Also as both of the lasers cleaved facets are parallel, the only thing which affects the relative distances is the misalignment between the mask and crystal axis. Given an angular misalignment of to up 0.05 degrees the two ridges should be within about 20 microns of each other in order to met the above criteria. After testing, a bond wire may be bonded to the bond pad of the determined best device from the testing process. FIG. 7 illustrates the situation described above.

In the discussion above we described one way of staggering the slot patterns on adjacent ridges with respect to each other. This was done directly by designing mask plates (optical lithography) or exposure patterns (e-beam lithography) in which these patterns were staggered. When the wavelength selective filters (slot patterns) are defined using optical or e-beam lithography this is by far the most straight forward way of staggering these filters with respect to each other. However it is also possible to change the phase between the wavelength filters and the facets by changing the effective index of part of the waveguide, or by intentionally misaligning the lithographic patterns with respect to the crystal axis by about 0.4 degrees. It is noted the last of these two methods may be applied to single mode lasers which have holographically defined gratings or wavelength selective filters defined by optical or e-beam lithography. The first of these methods however could only applied to structures in which holographically defined gratings extend along only portion of the cavity length.

First we discuss the effect of altering the effective index of part of one of the stripes of a dual stripe laser. FIG. 8 shows a dual stripe laser. The effective index of the light guided by the left hand stripe is constant along the length of the device. However the effective index of the light under the strip on the right has either one of two values. It's important to note that the portion of the right hand containing the wavelength selective filter should have the same effective index as the left hand stripe. Otherwise each stripe would lase at a substantially different wavelength.

It is also possible to alter the phase difference between the facet and wavelength selective filters on adjacent ridges by deliberately misaligning the mask with respect to the crystal axis. This angular this alignment is chosen so as to have the same effect as wavelength filters directly staggered with respect to each other, and misaligned to the crystal axis by less than 0.05 degrees. So in the new situation the angular misalignment would be something in the region of 0.5±0.05. The smaller the error in the angular alignment, the smaller the actual angular misalignment needs to be. As the optical properties of the devices may be affected by large angular misalignments, they should be kept as smaller possible. This may be achieved by increasing the distance between adjacent stripes. This may be accomplished (without increasing the overall device size) by placing one of the bondpads of the two devices between the two devices (see FIG. 9)

Depending on the precise positioning of the wavelength selective filters with respect to the facets of the device a discrete mode laser will lase in one several modes. This effect is most readily seen by testing a number of adjacent dual devices (approx 55) on a cleaved bar. It will be appreciated that the number of modes which have the capability to lase can be specified by using an appropriate pattern of slot features. FIG. 11 below shows how the emission wavelength of identical discrete mode dual lasers (as described above) varies with their bar position. The results are illustrated separately for the left and right stripes of each of these devices. In the exemplary devices used for the test, the slot pattern on the right stripe was shifted by

$$\frac{{λ}_{m}}{4}$$

with respect to the pattern on the left stripe for each device. This is why the variation of the emission wavelength with respect to device position is similar on the left and right stripes, but shifted with respect to each other. It is noted the more central bands of the wavelength distribution perform best, because of this the performance benefit is obvious. In devices in which the left hand stripe lases in one of the extremum wavelengths (e.g. device number 11), then the right hand stripe will lase in one of the more central wavelengths. The situation is similar if one of the right hand stripes lases in one of the extremum wavelengths (e.g. device number 30).

Finally we consider an exemplary device containing two different types of device, for example a Fabry Perot chip and a single frequency laser diode. The motivation for this, with reference to the example is as follows, the yield of Fabry Perot device is almost 100%, if the single mode laser doesn't work correctly there is almost a 100% chance that this chip will still be useful. FIG. 10 illustrates this configuration.

1.-22. (canceled)

23. A semiconductor lasing device comprising at least two lasing devices formed on a common substrate wherein the lasing device is arranged so that in use a preferred lasing device is operational and remaining lasing devices are redundant.

24. A semiconductor lasing device according to claim 23, where each laser device comprise wavelength selective structures wherein the wavelength selective structures of the at least two laser devices are offset from one another with respect to their respective facets.

25. A semiconductor lasing device according to claim 24, wherein there are N laser devices and where the offset between the individual laser devices is substantially mλ/4n_{eff}, where m is an odd integer.

26. A semiconductor lasing device according to claim 25 where N is 2.

27. A semiconductor lasing device according to claim 23, wherein the at least two laser devices comprise a first laser device and a second laser device wherein the first laser device and second laser device are different types of laser.

28. A semiconductor lasing device according to claim 27, wherein the first laser device is a single frequency laser diode.

29. A semiconductor lasing device according to claim 28, wherein the first laser device is a fabry perot diode.

30. A semiconductor lasing device according to claim 23, wherein an external connection is provided to the preferred lasing device but not the remaining lasing devices.

31. A semiconductor device according to claim 30, wherein the external connection comprises a bond wire.

32. A method of manufacturing a lasing device comprising the steps of:
a. providing a substrate,
b. fabricating at least two lasing devices on the substrate,
c. determining a preferred lasing device from the at least two lasing devices, and
d. configuring the lasing device so that the preferred lasing device is actively connected and remaining devices are redundant.

33. A method of manufacturing according to claim 32, wherein the method comprises the steps of fabricating wavelength selective features on each of the at least two lasing devices.

34. A method of manufacturing according to claim 33, wherein the wavelength selective features of the lasing devices are staggered with respect to one another.

35. A method of manufacturing according to claim 34 wherein the staggering is by a distance of mλ/4n_{eff} where λ is the wavelength of the devices and n is the number of devices, where m is an odd integer.

36. A method of manufacturing according to claim 32, wherein the distance between adjacent ridges is less than or about 20 microns.

37. A method of manufacturing according to claim 32, wherein the at least two devices are fabricated to be out of phase with one and other.

38. A method of manufacturing according to claim 37, wherein the phase difference is provided by changing the effective index of part of one of the devices.

39. A method of manufacturing according to claim 37, wherein the phase difference is obtained by misaligning the lithographic patterns with respect to the crystal axis.

40. A method according to claim 39, wherein the misalignment is of the order of about 0.5 degrees.

41. A method according to claim 40, wherein the angular misalignment is 0.5±0.1.

42. A method of manufacture according to claim 32, wherein the at least two lasing devices comprise a first lasing device and a second lasing device, where the first lasing device is a first type and the second lasing device is a second type.

43. A method of manufacture according to claim 32, wherein the second type of device is a Fabry Perot device.

44. A method of manufacture according to claim 43, wherein the first type of device is a single frequency laser diode.
